(19) United States
(12) Patent Application Publication
(10) Pub. No.: US 2023/0256999 A1
(43) Pub. Date: Aug. 17, 2023

(54) SIMULATION OF IMMINENT CRASH TO MINIMIZE DAMAGE INVOLVING AN AUTONOMOUS VEHICLE

(71) Applicant: GM Cruise Holdings LLC, San Francisco, CA (US)

(72) Inventor: Burkay Donderici, Burlingame, CA (US)

(21) Appl. No.: 17/674,475

(22) Filed: Feb. 17, 2022

(51) Int. Cl. B60W 60/00; B60W 30/085; B60W 50/035; G06F 30/27; G06N 20/00; G05B 17/02

(52) U.S. Cl. CPC B60W 60/0016; B60W 30/085; B60W 50/035; G06F 30/27; G06N 20/00; G05B 17/02; B60W 2050/0013

(57) ABSTRACT

The subject disclosure relates to techniques for minimizing damage for collisions including an autonomous vehicle. A process of the disclosed technology can include predicting that a crash involving the autonomous vehicle is imminent, altering at least one operational parameter of the autonomous vehicle after predicting the crash is imminent, performing a first simulation on the autonomous vehicle, wherein the first simulation is a simulation of the autonomous vehicle taking a first action to minimize damage from the crash, and generating a first damage estimate for the first simulation.

### 1. TECHNICAL FIELD

The subject technology pertains to minimizing damage of collisions involving an autonomous vehicle, and in particular, the subject technology pertains to simulating a first action and a second action and selecting one of the actions to minimize the damage of an imminent collision.

### 2. INTRODUCTION

Autonomous vehicles are vehicles having computers and control systems that perform driving and navigation tasks that are conventionally performed by a human driver. As autonomous vehicle technologies continue to advance, ridesharing services will increasingly utilize autonomous vehicles to improve service efficiency and safety. However, autonomous vehicles will be required to perform many of the functions that are conventionally performed by human drivers, such as avoiding dangerous or difficult routes, and performing other navigation and routing tasks necessary to provide safe and efficient transportation. Such tasks may require the collection and processing of large quantities of data disposed on the autonomous vehicle.

### BRIEF DESCRIPTION OF THE DRAWINGS

The embodiments herein may be better understood by referring to the following description in conjunction with the accompanying drawings in which like reference numerals indicate identically or functionally similar elements, of which:

FIG. 1 illustrates an example of a system for managing one or more Autonomous Vehicles (AVs) in accordance with some aspects of the present technology.

FIG. 2 illustrates an environment having an autonomous vehicle and other objects, in accordance with some aspects of the present technology.

FIG. 3 is a flowchart of a method for minimizing damage involving an autonomous vehicle in accordance with some aspects of the present technology.

FIG. 4 shows an example of a system for implementing certain aspects of the present technology.

### DETAILED DESCRIPTION

Autonomous vehicles are vehicles having computers and control systems that perform driving and navigation tasks that are conventionally performed by a human driver. As autonomous vehicle technologies continue to advance, ridesharing services will increasingly utilize autonomous vehicles to improve service efficiency and safety. However, autonomous vehicles will be required to perform many of the functions that are conventionally performed by human drivers, such as avoiding dangerous or difficult routes, and performing other navigation and routing tasks necessary to provide safe and efficient transportation. Such tasks may require collecting and processing large quantities of data disposed on the autonomous vehicle.

Autonomous vehicles utilize various sensor systems to perceive an environment in which the autonomous vehicles operate. These sensor systems are particularly important to autonomous vehicles because they provide an avenue for the autonomous vehicles to perceive and interpret the world around them so that the autonomous vehicles can operate safely and efficiently.

Processing the sensor data and performing other tasks requires large amounts of computational power. As more sensors are added onto autonomous vehicles and as autonomous vehicles begin handling more complex decisions and tasks, the computational power on-board the autonomous vehicle may be stressed. More specifically, the amount of computation resources on-board the autonomous vehicle is limited to a certain amount at any given time. These resources are expended on processing sensor data, using data to make decisions, and performing tasks. Thus, the computational resources on-board the autonomous vehicle must be utilized efficiently for safe operation of the autonomous vehicle.

Even when the autonomous vehicle is operating safely, there may be situations where a collision involving the autonomous vehicle is imminent. In other words, through no fault of the autonomous vehicle, a collision may still occur. In these situations, minimizing damage is the best possible choice. Thus, it is important for the autonomous vehicle to minimize total damage including property damage and any human injuries. While the present technology might imply value judgments to be made by an autonomous vehicle, it will be appreciated that this is only for purposes of explaining how the present technology might work. No statement herein should be used to imply that any autonomous vehicle is making value judgments in this way, or that the technology will be deployed on an autonomous vehicle.

Accordingly, the present technology provides solutions for minimizing collective damage for collisions involving an autonomous vehicle. More specifically, the autonomous vehicle can process sensor data perceived by sensors of the autonomous vehicle to determine that a collision is imminent. The autonomous vehicle can then alter operational parameters of the autonomous vehicle to improve the compute capability of the autonomous vehicle to attempt to minimize damage during the imminent collision. For example, the autonomous vehicle can reduce the usage of sensors on-board the autonomous vehicle (e.g., by powering off one or more sensors, reducing physical range of one or more sensors, etc.). By altering operational parameters, the autonomous vehicle can leverage more of the computational resources to simulate possible actions of the autonomous vehicle and to generate a damage estimate if the autonomous vehicle were to undertake the possible action. In sum, the autonomous vehicle can utilize any additional compute power to perform more simulations faster in an effort to find a better outcome of the imminent collision than taking no action or a less good action.

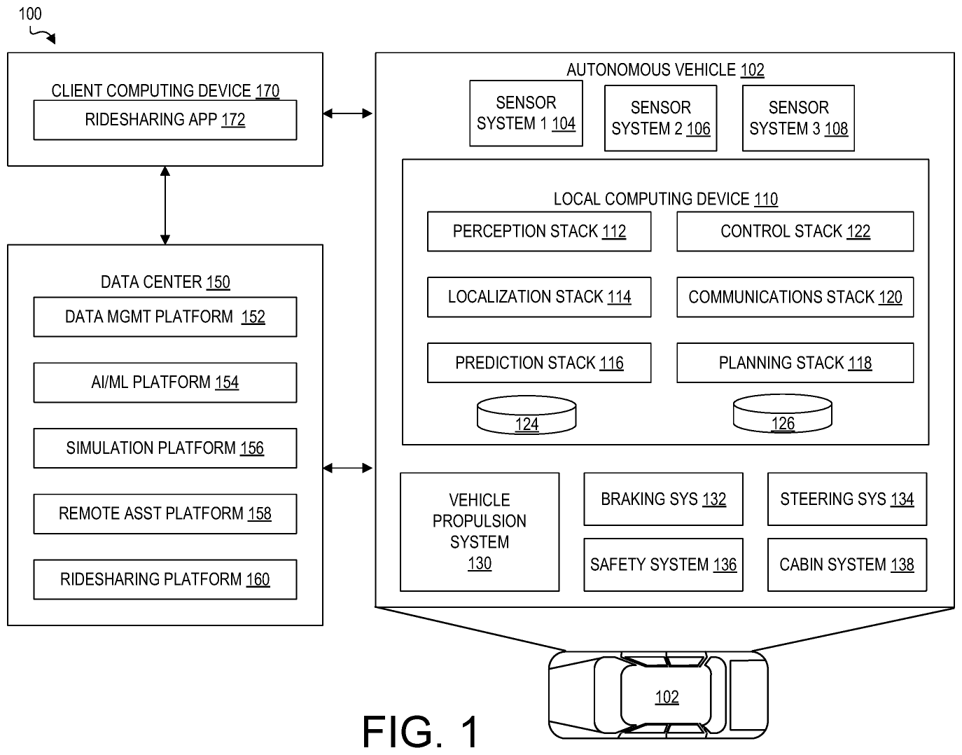

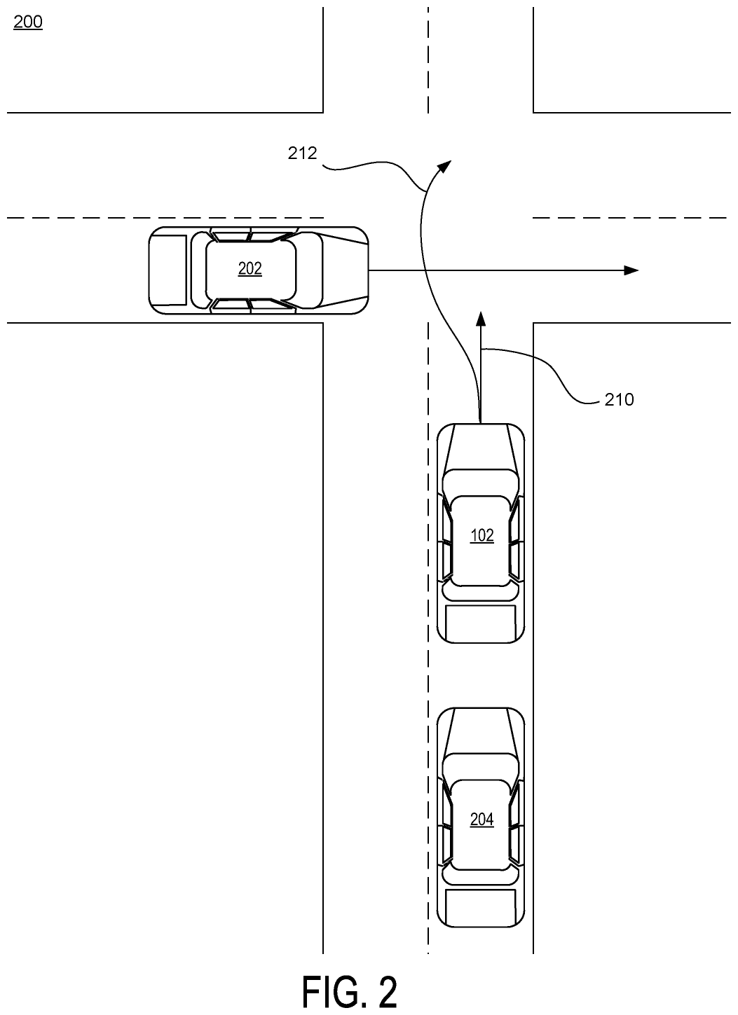

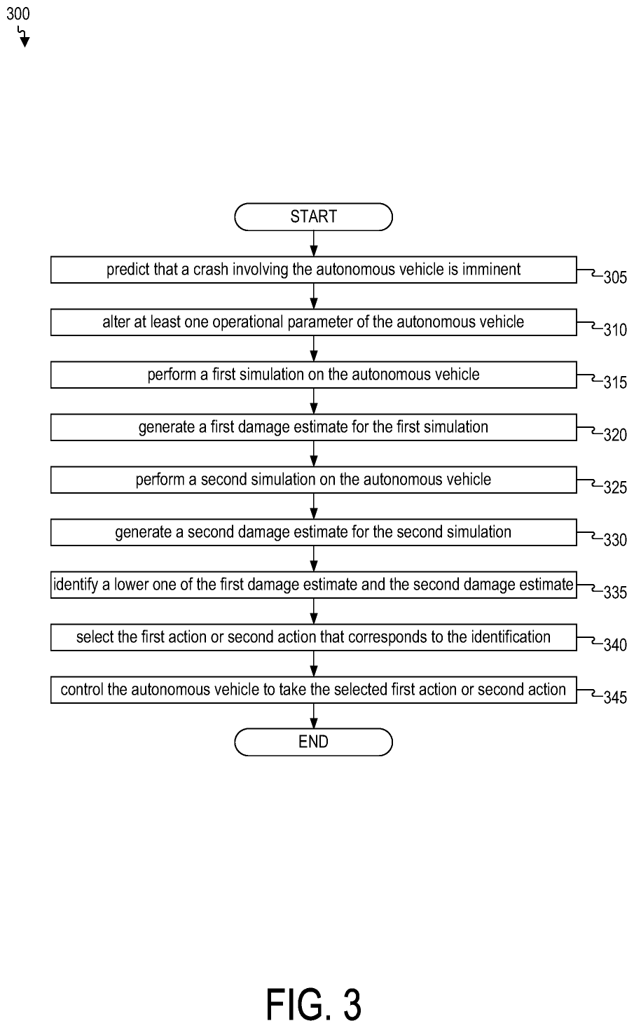

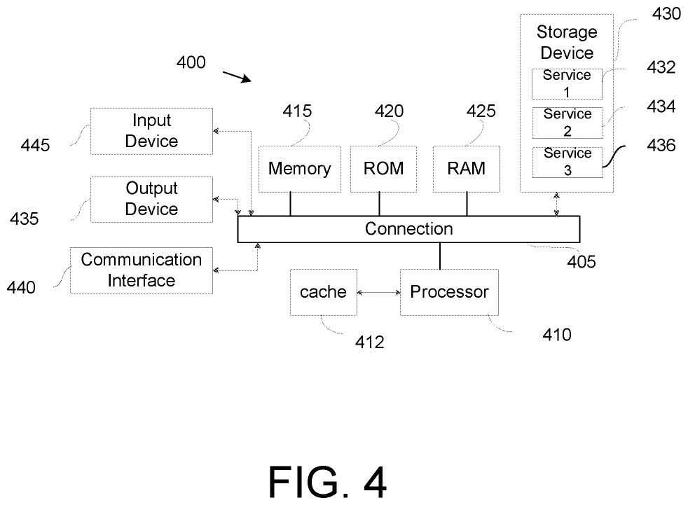

A description of an AV management system, as illustrated in FIG. 1, is first disclosed herein. An example environment having an autonomous vehicle and various other objects is disclosed in FIG. 2 and is followed by a method performed by a computing system in FIG. 3. The discussion concludes with a brief description of example devices, as illustrated in FIG. 4. These variations shall be described herein as the various embodiments are set forth. The disclosure now turns to FIG. 1.

FIG. 1 illustrates an example of an autonomous vehicle (AV) management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., light detection and ranging (LIDAR) systems, ambient light sensors, infrared sensors, etc.), RADAR systems, global positioning system (GPS) receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some embodiments, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and a high definition (HD) geospatial database 126, among other stacks and systems.

The perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth. In some embodiments, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.). The bounding area may by defined on grid that consists of a rectangular, cylindrical or spherical projection of the camera or LIDAR data.

The mapping and localization stack 114 can determine the AV's position and orientation (pose) using different methods from multiple systems (e.g., GPS, IMUS, cameras, LIDAR, RADAR, ultrasonic sensors, the HD geospatial database 126, etc.). For example, in some embodiments, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some embodiments, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point. In some embodiments, the prediction stack 116 can output a probability distribution of likely paths or positions that the object is predicted to take.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls lane can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some embodiments, the raw AV data can include HD LIDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can be a private cloud (e.g., an enterprise network, a co-location provider network, etc.), a public cloud (e.g., an IaaS network, a PaaS network, a SaaS network, or other CSP network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structured (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smartwatch, smart eyeglasses or other Head-Mounted Display (HMD), smart ear pods, or other smart in-ear, on-ear, or over-ear device, etc.), gaming system, or other general purpose computing device for accessing the ridesharing application 172. The client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

FIG. 2 illustrates an example environment 200 having an autonomous vehicle 102 and other objects 202, 204. More specifically, objects 202, 204 can be other vehicles nearby autonomous vehicle 102. For example, vehicle 202 can be a vehicle crossing a street ahead of autonomous vehicle 102, while vehicle 204 follows behind autonomous vehicle 102. Additionally, autonomous vehicle 102 may have the right of way due to a stop light indicating a green light for autonomous vehicle 102, while the stop light indicates a red light for vehicle 202. In other words, FIG. 2 shows vehicle 202 running a red light, while autonomous vehicle 102 has the right of way. In some instances, this can result in an unavoidable collision between autonomous vehicle 102 and vehicle 202.

Autonomous vehicle 102 can determine or predict if a crash is imminent based on various factors. For example, autonomous vehicle 102 can calculate collision imminency using a kinematic simulation of autonomous vehicle 102 and location and/or shape of other objects (e.g., objects 202, 204), a kinematic simulation of autonomous vehicle 102 and an occupancy map, a machine-learning model of vehicle kinematics and interaction with other objects (e.g., objects 202, 204), planning data generated by planning stack 118, comparison of a collision probability with a threshold, etc.

While the collision may be unavoidable, autonomous vehicle 102 may be able to minimize or reduce collective damage caused by the collision. More specifically, autonomous vehicle 102 can simulate and analyze various possible control settings or actions 210, 212. For example, autonomous vehicle 102 can simulate autonomous vehicle 102 taking a first action 210 that is a hard brake. Thus, autonomous vehicle 102 can perform a first simulation of a hard braking action 210 and generate a first damage estimate based on the hard braking action 210. In some instances, the first action may not be the best course of action. For example, if autonomous vehicle 102 were to hard brake 210 to avoid a collision with vehicle 202, vehicle 204 may be too close to safely respond, which may result in vehicle 204 rear-ending autonomous vehicle 102. Additionally, autonomous vehicle 102 may have a second action 212 that is swerving behind vehicle 202. Thus, autonomous vehicle 102 can perform a second simulation of a swerving action 212 and generate a second damage estimate based on the swerving action 212. In some embodiments, the first and/or second actions may be selected from preset actions. In some embodiments, the first and/or second actions may be selected based on planning data. Additionally, the simulations can be mechanical simulations that model any of the pressure, velocity, displacement, position, or structural integrity of the objects in the scene. In some embodiments, the simulations can be performed by a machine-learning model. In some embodiments, the simulations can utilize perception stack 112, localization stack 114, prediction stack, 116, planning stack 118, communications stack 120, control stack 122, AV operational database 124, and/or HD geospatial database 126. Furthermore, the simulations can receive and utilize sensor data, perception data, prediction data, planning data, current trajectories, drive plans for the autonomous vehicle, etc. In some embodiments, the actions simulated can include maneuvers that are different from actions that planning stack 118 would use. For example, planning stack 118 may determine a simple path towards a destination (e.g., go straight) and prioritize a smooth ride and low cost (e.g., avoiding collisions). Simulations could have different driving parameters and/or priorities.

The damage estimates can include analyses of data from the simulations. In some embodiments, a machine-learning model can generate the damage estimates. In some embodiments, the damage estimates can also include probabilities of damage. Additionally, the damage estimates can indicate the amount of damage that would occur if autonomous vehicle 102 were to take the first action 210. For example, the first damage estimate can include the amount of damage to vehicle 202, autonomous vehicle 102, and/or vehicle 204. More specifically, if autonomous vehicle 102 were to stop hard enough to avoid a collision with vehicle 202, the damage estimate can indicate no damage to vehicle 202. Additionally, if the hard stop results in vehicle 204 rear-ending autonomous vehicle 102, then the damage estimate can estimate the amount of damage to the autonomous vehicle and vehicle 204. Furthermore, the damage estimate can take into account any potential damage or danger to passengers within autonomous vehicle 102 and/or vehicles 202, 204. For example, one collision may result in substantial bodily harm to a passenger in a vehicle, while another collision may result simply in property damage. The autonomous vehicle 102 can be programmed to assign a high (or infinite) amount of damage for any type of substantial bodily harm, so that the autonomous vehicle 102 will always choose to avoid collisions that cause substantial bodily harm.

Performing these simulations and generating damage estimates can use a large amount of computational resources. Thus, the present technology also contemplates altering operational parameters of autonomous vehicle 102. More specifically, when autonomous vehicle 102 determines that a collision is unavoidable, autonomous vehicle 102 can change operational parameters by turning all sensors off, turning sensors that are not measuring the objects that play a role in the imminent collision off, turning cameras off, restricting or reducing processing physical range of sensors, diverting processing power to select systems (e.g., simulation module, controls, etc.), replacing at least one model on-board autonomous vehicle 102 (e.g., a deep-learning model) with a pre-calculating optimized model, optimizing at least one model on autonomous vehicle 102 (e.g, by one-shot pruning, quantization, etc.), increasing a frequency of critical compute (e.g., by increasing a number of ticks per second). The above mechanisms can all result in freeing up additional compute power to allow the autonomous vehicle to utilize the additional compute power to find a plan that leads to lowest damage as a result of the imminent collision. In many cases, the techniques listed above to free up compute power can involve deprioritizing systems that are not needed in an imminent accident scenario.

For example, usage of perception stack 112 can be reduced, restricted, and/or stopped because perceiving new objects is no longer important. Thus, autonomous vehicle 102 can shut off sensors that are inputs to perception stack 112. As another example, usage of localization stack 114 can be reduced, restricted, and/or stopped because autonomous vehicle 102 already knows a current location of all objects in the environment around autonomous vehicle. As yet another example, usage of prediction stack 116 can be reduced, restricted, and/or stopped because a collision has already been predicted. As yet another example, planning stack 118 can be reduced, restricted, and/or stopped because planning could be delegated to a route determined by the simulations.

In some embodiments, autonomous vehicle 102 can create or have a compute budget for damage simulation, such that altering sensor usage is based on an estimate of current usage of compute compared to the compute budget. The compute of the autonomous vehicle 102 can be calculated based on throughput, time, or memory. The calculation of the compute can be performed by monitoring the running processes and measuring the throughput, time, or memory of each process. The calculation of the compute can also be performed by an estimator that can estimate throughput, time, or memory based on an analytical or machine learning model. The compute budget of the autonomous vehicle 102 is based on the hardware used and, in some embodiments, can be nearly fully utilized in normal operation. The additional compute that is needed for the damage estimate can be calculated in terms of throughput, time, or memory as mentioned above. The savings of turning off each sensor can also be similarly calculated. Finally, the set of sensors that need to be turned off can be determined by turning off sensors that are contributing least to the safe operation of the autonomous vehicle 102 in moments leading up to the crash until there is enough bandwidth in the compute budget for the damage estimate.

FIG. 3 illustrates an example method 300 for minimizing damage from collisions involving an autonomous vehicle. Although the example method 300 depicts a particular sequence of operations, the sequence may be altered without departing from the scope of the present disclosure. For example, some of the operations depicted may be performed in parallel or in a different sequence that does not materially affect the function of the method 300. In other examples, different components of an example device or system that implements the method 300 may perform functions at substantially the same time or in a specific sequence.

In some embodiments, method 300 includes predicting 305 that a crash involving the autonomous vehicle is imminent. For example, local computing device 110 illustrated in FIG. 1 may predict 305 that a crash involving the autonomous vehicle is imminent. The imminence of the crash may be determined by the planning stack 118 by checking a number of possible actions by the autonomous vehicle 102 and finding that all leads to the crash.

In some embodiments, method 300 includes altering 310 at least one operational parameter of the autonomous vehicle after predicting the crash is imminent. For example, local computing device 110 illustrated in FIG. 1 may alter 310 at least one operational parameter of the autonomous vehicle after predicting the crash is imminent. In some embodiments, altering 310 the operational parameters of the autonomous vehicle includes at least one of turning off a sensor of the autonomous vehicle, restricting a physical range of at least one sensor, diverting processing power to critical systems, replacing at least one model on the autonomous vehicle, pausing or terminating processing functions, optimizing at least one model on the autonomous vehicle, and increasing a frequency of compute. In some embodiments, altering 310 the operational parameters includes turning off sensors based on a compute budget for damage simulation. In some embodiments, altering the operational parameters can include discontinuing operation of any sensor or software operation in favor of processing used to minimize damage from the imminent collision. In some embodiments, altering the operational parameters can include overclocking the processors, or repurposing processors from other tasks to perform operations such as those addressed below.

In some embodiments, method 300 includes performing 315 a first simulation on the autonomous vehicle. For example, local computing device 110 illustrated in FIG. 1 may perform 315 a first simulation on the autonomous vehicle. In some embodiments, the first action is selected from presets. In some embodiments, the first action is generated based on planning data. In some embodiments, the first simulation is a simulation of the autonomous vehicle taking a first action to minimize damage from the crash. In some embodiments, the first simulation is simulated by a machine-learning model. In some embodiments, the first simulation is performed by a mechanical model that models any of pressure, velocity, displacement, position, or structural integrity of any of the objects involved in the crash

In some embodiments, method 300 includes generating 320 a first damage estimate for the first simulation. For example, local computing device 110 illustrated in FIG. 1 may generate 320 a first damage estimate for the first physical simulation.

In some embodiments, method 300 includes performing 325 a second simulation. For example, local computing device 110 illustrated in FIG. 1 may perform 325 a second simulation. In some embodiments, the second simulation is a simulation of the autonomous vehicle taking a second action to minimize damage from the crash.

In some embodiments, method 300 includes generating 330 a second damage estimate for the second simulation. For example, local computing device 110 illustrated in FIG. 1 may generate 330 a second damage estimate for the second simulation.

In some embodiments, method 300 includes identifying 335 a lower one of the first damage estimate and the second damage estimate. For example, local computing device 110 illustrated in FIG. 1 may identify 335 a lower one of the first damage estimate and the second damage estimate. In other words, local computing device 110 can identify a lower damage estimate that minimizes collective damage including to damage to other property and any human injuries, not just damage to autonomous vehicle 102.

In some embodiments, method 300 includes selecting 340 the first action or the second action that corresponds to the identification of the lower one of the first damage estimate and the second damage estimate. For example, local computing device 110 illustrated in FIG. 1 may select 340 the first action or the second action that corresponds to the identification of the lower one of the first damage estimate and the second damage estimate.

In some embodiments, method 300 includes controlling 345 the autonomous vehicle to take the selected first action or second action. For example, local computing device 110 illustrated in FIG. 1 may control 345 the autonomous vehicle to take the selected first action or second action.

While the method described above referred to a first action and first simulation and a second action and a second simulation, it should be appreciated by those of ordinary skill it the art that any number of actions can be considered through any number of simulations provided that there is enough time and compute resourced. Additionally, it should be appreciated that simulations can be performed by parallel threads and they do not need to be performed in sequence.

FIG. 4 shows an example of computing system 400, which can be for example any computing device making up autonomous vehicle 102, local computing device 110, data center 150, client computing device 170 or any component thereof in which the components of the system are in communication with each other using connection 405. Connection 405 can be a physical connection via a bus, or a direct connection into processor 410, such as in a chipset architecture. Connection 405 can also be a virtual connection, networked connection, or logical connection.

In some embodiments, computing system 400 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 400 includes at least one processing unit (CPU or processor) 410 and connection 405 that couples various system components including system memory 415, such as read-only memory (ROM) 420 and random access memory (RAM) 425 to processor 410. Computing system 400 can include a cache of high-speed memory 412 connected directly with, in close proximity to, or integrated as part of processor 410.

Processor 410 can include any general purpose processor and a hardware service or software service, such as services 432, 434, and 436 stored in storage device 430, configured to control processor 410 as well as a special-purpose processor where software instructions are incorporated into the actual processor design. Processor 410 may essentially be a completely self-contained computing system, containing multiple cores or processors, a bus, memory controller, cache, etc. A multi-core processor may be symmetric or asymmetric.

To enable user interaction, computing system 400 includes an input device 445, which can represent any number of input mechanisms, such as a microphone for speech, a touch-sensitive screen for gesture or graphical input, keyboard, mouse, motion input, speech, etc. Computing system 400 can also include output device 435, which can be one or more of a number of output mechanisms known to those of skill in the art. In some instances, multimodal systems can enable a user to provide multiple types of input/output to communicate with computing system 400. Computing system 400 can include communications interface 440, which can generally govern and manage the user input and system output. There is no restriction on operating on any particular hardware arrangement, and therefore the basic features here may easily be substituted for improved hardware or firmware arrangements as they are developed.

Storage device 430 can be a non-volatile memory device and can be a hard disk or other types of computer readable media which can store data that are accessible by a computer, such as magnetic cassettes, flash memory cards, solid state memory devices, digital versatile disks, cartridges, random access memories (RAMs), read-only memory (ROM), and/or some combination of these devices.

The storage device 430 can include software services, servers, services, etc., that when the code that defines such software is executed by the processor 410, it causes the system to perform a function. In some embodiments, a hardware service that performs a particular function can include the software component stored in a computer-readable medium in connection with the necessary hardware components, such as processor 410, connection 405, output device 435, etc., to carry out the function.

For clarity of explanation, in some instances, the present technology may be presented as including individual functional blocks including functional blocks comprising devices, device components, steps or routines in a method embodied in software, or combinations of hardware and software.

Any of the steps, operations, functions, or processes described herein may be performed or implemented by a combination of hardware and software services or services, alone or in combination with other devices. In some embodiments, a service can be software that resides in memory of a client device and/or one or more servers of a content management system and perform one or more functions when a processor executes the software associated with the service. In some embodiments, a service is a program or a collection of programs that carry out a specific function. In some embodiments, a service can be considered a server. The memory can be a non-transitory computer-readable medium.

In some embodiments, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer-readable media. Such instructions can comprise, for example, instructions and data which cause or otherwise configure a general purpose computer, special purpose computer, or special purpose processing device to perform a certain function or group of functions. Portions of computer resources used can be accessible over a network. The executable computer instructions may be, for example, binaries, intermediate format instructions such as assembly language, firmware, or source code. Examples of computer-readable media that may be used to store instructions, information used, and/or information created during methods according to described examples include magnetic or optical disks, solid-state memory devices, flash memory, USB devices provided with non-volatile memory, networked storage devices, and so on.

Devices implementing methods according to these disclosures can comprise hardware, firmware and/or software, and can take any of a variety of form factors. Typical examples of such form factors include servers, laptops, smartphones, small form factor personal computers, personal digital assistants, and so on. The functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

What is claimed is:

1. A computer-implemented method for minimizing damage in a collision involving an autonomous vehicle, the method comprising:
predicting that a crash involving the autonomous vehicle is imminent;
altering at least one operational parameter of the autonomous vehicle after predicting the crash is imminent;
performing a first simulation on the autonomous vehicle, wherein the first simulation is a simulation of the autonomous vehicle taking a first action to minimize damage from the crash; and
generating a first damage estimate for the first simulation.

2. The computer-implemented method of claim 1, further comprising:
performing a second simulation, wherein the second simulation is a simulation of the autonomous vehicle taking a second action to minimize damage from the crash
generating a second damage estimate for the second simulation;
identifying a lower one of the first damage estimate and the second damage estimate; and
selecting the first action or the second action that corresponds to the identification of the lower one of the first damage estimate and the second damage estimate.

3. The computer-implemented method of claim 2, further comprising:
controlling the autonomous vehicle to take the selected first action or second action.

4. The computer-implemented method of claim 1, wherein altering the operational parameters of the autonomous vehicle includes at least one of turning off at least one sensor of the autonomous vehicle, restricting a physical range of at least one sensor, diverting processing power to critical systems, replacing at least one model on the autonomous vehicle, optimizing at least one model on the autonomous vehicle, and increasing a frequency of compute.

5. The computer-implemented method of claim 1, wherein altering the operational parameters includes turning off sensors based on a compute budget for damage simulation.

6. The computer-implemented method of claim 1, wherein the first action is selected from presets.

7. The computer-implemented method of claim 1, wherein the first action is generated based on planning data.

8. The computer-implemented method of claim 1, wherein the first simulation is simulated by a machine-learning model.

9. A system comprising:
a storage configured to store instructions;
a processor configured to execute the instructions and cause the processor to:
predict that a crash involving the autonomous vehicle is imminent,
alter at least one operational parameter of the autonomous vehicle after predict the crash is imminent,
perform a first simulation on the autonomous vehicle, wherein the first simulation is a simulation of the autonomous vehicle taking a first action to minimize damage from the crash, and
generate a first damage estimate for the first simulation.

10. The system of claim 9, wherein the processor is configured to execute the instructions and cause the processor to:
perform a second simulation, wherein the second simulation is a simulation of the autonomous vehicle taking a second action to minimize damage from the crash;
generate a second damage estimate for the second simulation;
identify a lower one of the first damage estimate and the second damage estimate; and
select the first action or the second action that corresponds to the identification of the lower one of the first damage estimate and the second damage estimate.

11. The system of claim 9, wherein altering the operational parameters of the autonomous vehicle includes at least one of turning off at least one sensor of the autonomous vehicle, restricting a physical range of at least one sensor, diverting processing power to critical systems, replacing at least one model on the autonomous vehicle, optimizing at least one model on the autonomous vehicle, and increasing a frequency of compute.

12. The system of claim 9, wherein altering the operational parameters includes turning off sensors based on a compute budget for damage simulation.

13. The system of claim 9, wherein the first action is selected from presets.

14. The system of claim 9, wherein the first action is generated based on planning data.

15. The system of claim 9, wherein the first simulation is simulated by a machine-learning model.

16. A non-transitory computer readable medium comprising instructions, the instructions, when executed by a computing system, cause the computing system to:
predict that a crash involving the autonomous vehicle is imminent;
alter at least one operational parameter of the autonomous vehicle after predict the crash is imminent;
perform a first simulation on the autonomous vehicle, wherein the first simulation is a simulation of the autonomous vehicle taking a first action to minimize damage from the crash; and
generate a first damage estimate for the first simulation.

17. The computer readable medium of claim 16, wherein the computer readable medium further comprises instructions that, when executed by the computing system, cause the computing system to:
perform a second simulation, wherein the second simulation is a simulation of the autonomous vehicle taking a second action to minimize damage from the crash;
generate a second damage estimate for the second simulation;
identify a lower one of the first damage estimate and the second damage estimate; and
select the first action or the second action that corresponds to the identification of the lower one of the first damage estimate and the second damage estimate.

18. The computer readable medium of claim 16, altering the operational parameters of the autonomous vehicle includes at least one of turning off at least one sensor of the autonomous vehicle, restricting a physical range of at least one sensor, diverting processing power to critical systems, replacing at least one model on the autonomous vehicle, optimizing at least one model on the autonomous vehicle, and increasing a frequency of compute.

19. The computer readable medium of claim 16, altering the operational parameters includes turning off sensors based on a compute budget for damage simulation.

20. The computer readable medium of claim 16, the first action is selected from presets.
